(19) United States
(12) Patent Application Publication
(10) Pub. No.: US 2025/0098209 A1
(43) Pub. Date: Mar. 20, 2025

(54) SEMICONDUCTOR DEVICE AND METHOD FOR FABRICATING THE SAME

(71) Applicant: UNITED MICROELECTRONICS CORP., Hsinchu (TW)

(72) Inventor: Shin-Hung LI, Nantou County (TW)

(21) Appl. No.: 18/383,055

(22) Filed: Oct. 24, 2023

(30) Foreign Application Priority Data
Sep. 14, 2023 (CN) 202311187909.8

(51) Int. Cl. H01L 29/78; H01L 29/10; H01L 29/40; H01L 29/66

(52) U.S. Cl. CPC H10D 30/65; H10D 30/0281; H10D 30/605; H10D 30/611; H10D 62/393; H10D 64/01

(57) ABSTRACT

A semiconductor device includes a substrate; a first well region disposed in the substrate and with a first electrical property; a second well region with the first electrical property disposed in the substrate and separated from the first well region; a first gate dielectric layer disposed on the first well region and having a first thickness; a second gate dielectric layer, disposed on the second well region, separated from the first gate dielectric layer and having a second thickness less than the first thickness; a first gate electrode disposed on the first gate dielectric layer; a second gate electrode disposed on the second gate dielectric layer and separated from the first gate electrode; a drain region disposed in the first well region; and a source region disposed in the second well region.

This application claims the benefit of People's Republic of China Application Serial No. 202311187909.8 filed at Sep. 14, 2023, the subject matter of which is incorporated herein by reference.

### BACKGROUND

### Technical Field

The disclosure relates to a semiconductor device and method for fabricating the same, and more particularly to a semiconductor device having a drain extended structure and method for fabricating the same.

### Description of Background

Semiconductor devices with drain extension structures, such as N-channel drain extended metal-oxide-semiconductor (nEDMOS) transistors, can control the output voltage of the drain terminal greater than the input voltage of the source terminal, by increasing the drift region at the drain terminal and/or by modulating the thickness of the gate dielectric layer. They are usually used in a level shifter in a display driving circuit.

Because a typical nEDMOS transistor has a gate dielectric layer with non-uniform thickness (for example, the portion close to the source terminal has a thinner thickness than the portion close to the drain terminal), more than two dielectric material patterning processes are generally used to form at least two sub-gate dielectric layers with different thicknesses on the substrate, and then the two are combined to form the gate dielectric layer with non-uniform thickness. Another method for forming the gate dielectric layer with non-uniform thickness includes steps as follows: Firstly, a dielectric material layer is formed on the substrate, and then the thickness of a portion of the dielectric material layer close to the source terminal can be reduce by an etching process.

However, no matter what method is used for manufacturing the nEDMOS transistor, it is easy to produce tip protrusions or slopes at the intersection of different portions of the gate dielectric layer with different thicknesses, which may result in gate height loss of the gate electrode subsequently formed on the gate dielectric layer.

Therefore, there is a need of providing a semiconductor device and method for fabricating the same to obviate the drawbacks encountered from the prior art.

### SUMMARY

One embodiment of the present disclosure is to provide a semiconductor device, wherein the semiconductor device includes a substrate, a first well region, a second well region, a first gate dielectric layer, a second gate dielectric layer, a first gate electrode, a second gate electrode, a source region and a drain region. The first well region is disposed in the substrate and has a first electrical property. The second well region is disposed in the substrate, is separated from the first well region, and has the first electrical property. The first gate dielectric layer is disposed above the first well region and has a first thickness. The second gate dielectric layer is disposed above the second well region, is separated from the first gate dielectric layer, and has a second thickness less than the first thickness. The first gate electrode is disposed above the first gate dielectric layer. The second gate electrode is disposed above the second gate dielectric layer and separated from the first gate electrode. The drain region is disposed in the first well region; and the source region is disposed in the second well region.

Another embodiment of the present disclosure provides a method for fabricating a semiconductor device, wherein the method includes steps as follows: Firstly, a first well region with a first electrical property and a second well region with the first electrical property are formed in a substrate, wherein the first well region and the second well region are separated from each other. Next, a first gate dielectric layer with a first thickness is formed over the first well region; a second gate dielectric layer with a second thickness is formed over the second well region, wherein the first gate dielectric layer and the second gate dielectric layers are separated from each other, and the first thickness is greater than the second thickness. A first gate electrode is then formed above the first gate dielectric layer; a second gate electrode is formed above the second gate dielectric layer, and the second gate electrode and the first gate electrode are separated from each other. Subsequently, a drain region is formed in the first well region; and a source region is formed in the second well region.

In accordance with the aforementioned embodiments of the present disclosure, a semiconductor device with a split gate structure is provided. Wherein, the split gate structure of the semiconductor device includes a first split gate structure and a second split gate structure that are separated from each other, and are independently formed on a first well region and a second well region that are separated from each other and that have the same electrical property. Since the first well region and the second well region are separated by a portion of the substrate body region, thus it can prevent the portion of the second well region close to the drain terminal from overlapping with the portion of the second split gate structure close to the source terminal, whereby the problems of drain current drop due to the overlapping can be resolved.

In addition, since the first gate dielectric layer and the second gate dielectric layer of the first split gate structure and the second split gate structure are respectively formed on the first well region and the second well region that are separated from each other, thus the manufacturing processes for forming these two may not interfere with each other, and no tip protrusions or slopes are generated at the adjacencies between the two, whereby it can ensure each of the first gate electrode and the second gate electrode that are subsequently formed on the first gate dielectric layer and the second gate dielectric layer has a preset height after planarization correspondingly without causing gate height loss.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIGS. 1A to FIG. 1D are cross-sectional views illustrating a series of processing structures for manufacturing a semiconductor device, according to one embodiment of the present disclosure;

FIGS. 2A to 2D are c cross-sectional views illustrating a series of processing structures for manufacturing a semiconductor device according to another embodiment of the present disclosure;

FIG. 3 is a cross-sectional view of a semiconductor device according to yet another embodiment of the present disclosure; and

FIG. 4 is a cross-sectional view of another semiconductor device according to yet another embodiment of the present disclosure.

### DETAILED DESCRIPTION

The embodiments as illustrated below provide a semiconductor device with a drain extension structure and a method for forming the same, which can solve the problem of gate electrode height loss caused by the manufacturing process of the semiconductor device. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

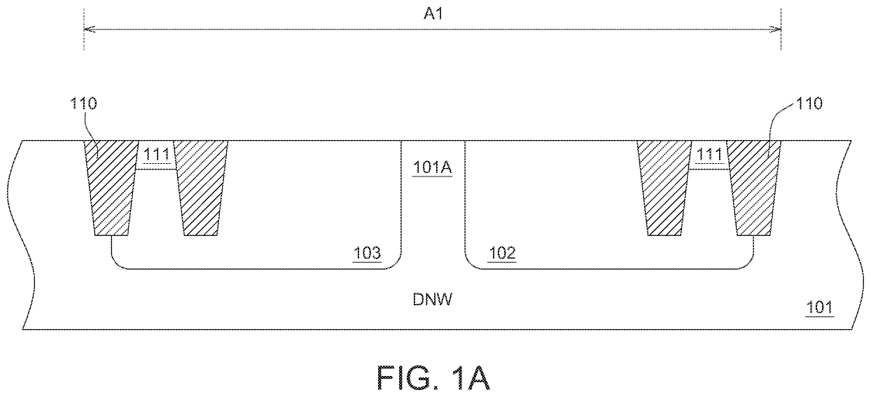

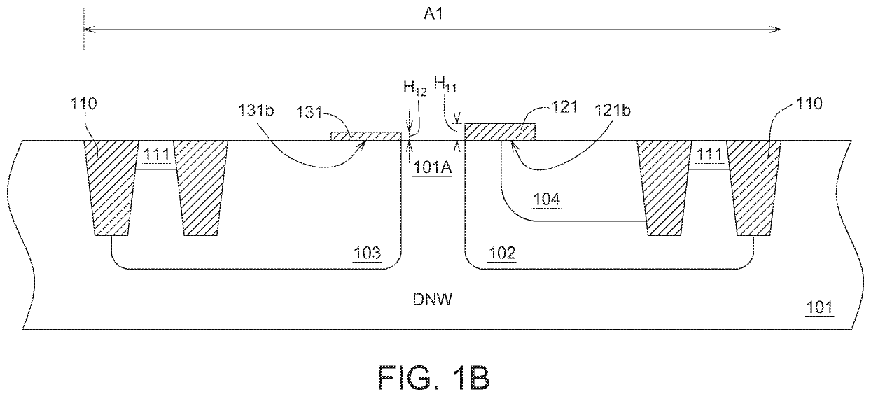

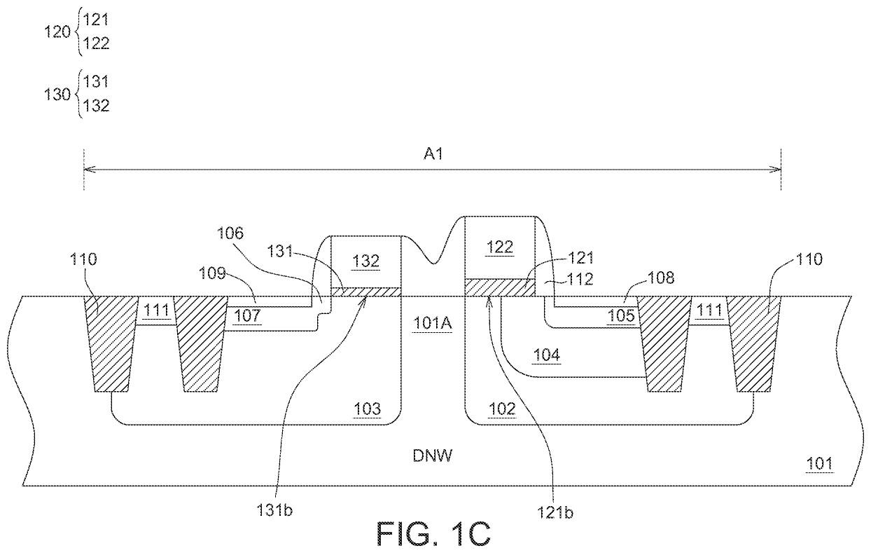

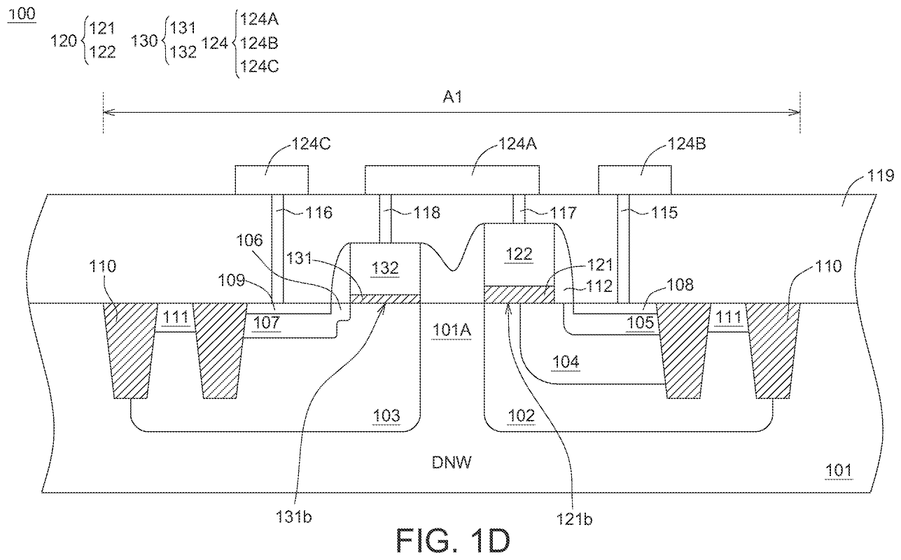

FIGS. 1A to FIG. 1D are cross-sectional views illustrating a series of processing structures for manufacturing a semiconductor device 100, according to one embodiment of the present disclosure. In some embodiments of the present disclosure, the semiconductor device 100 may be an N-channel drain extended metal-oxide-semiconductor (nEDMOS) transistor including a split polysilicon gate structure. The method of manufacturing the semiconductor device 100 includes steps as follows:

Firstly, a semiconductor substrate 101 is provided, and a shallow trench isolation structure 110 is formed in the semiconductor substrate 101 to define an device region A1 in the semiconductor substrate 101 (as shown in FIG. 1A). In some embodiments of the present disclosure, the semiconductor substrate 101 may be a silicon substrate (e.g., a silicon wafer) having dopants with a second electrical property (N-type electrical property). In other embodiments of the present invention, the semiconductor substrate 101 may be a silicon substrate having a deep well region with a second electrical property (e.g., an N-type electrical property), such as a silicon substrate having an n-doped deep well region (DNW)).

Next, at least one ion implantation process is performed to form a first well region 102 and a second well region 103 that have the same electrical property and are separated from each other in the semiconductor substrate 101. And a lightly doped region 104 having the second electrical property (N-type electrical property) is then formed in the first well region 102. For example, in the present embodiment, the first well region 102 and the second well region 103 having a first electrical property (e.g., P-type electrical property) are simultaneously formed in the DNW (third well region) in the device region A1 of the semiconductor substrate 101 by the same ion doping process. The lightly doped region 104 having the second electrical property (N-type electrical property) is then formed in the second well region 102 of the semiconductor substrate 101 by another ion doping process. Wherein the first well region 102 and the second well region 103 are separated from each other by a portion of a native region 101A of the semiconductor substrate 101. And the doping concentration of the first well region 102 is smaller than the doping concentration of the second well region 103.

However, the steps of forming the first well region 102 and the second well region 103 are not limited to this regard. For example, in another embodiment, the first well region 102 and the second well region may be formed by different ion doping processes. In addition, in some embodiments, two heavily doped regions 111 having the first electrical property (P-type electrical property) may be formed respectively in the first well region 102 and the second well region 103 by another ion doping process. The doping concentration of the heavily doped region 111 is greater than the doping concentration of the first well region 102.

Thereafter, a first gate dielectric layer 121 with a first thickness H11 is formed on the first well region 102; a second gate dielectric layer 131 with a second thickness H12 is formed on the second well region 103, wherein the first gate dielectric layer 121 and the second gate dielectric layer 131 are separated from each other, and the first thickness H11 is greater than the second thickness H12. In the present embodiment, as shown in FIG. 1B, the bottom surface 121b of the first gate dielectric layer 121 substantially flush with the bottom surface 131b of the second gate dielectric layer 131.

For example, in some embodiments of the present disclosure, the first gate dielectric layer 121 and the second gate dielectric layer 131 can be formed on the first well region 102 and the second well region 103 by two different dielectric material deposition and patterning processes. Wherein the first gate dielectric layer 121 and the second gate dielectric layer 131 may be a single-layer or multi-layer structure.

The materials constituting the first gate dielectric layer 121 and the second gate dielectric layer 131 may be the same or different dielectric materials. And these dielectric materials can be selected from a group consisting of, for example, silicon dioxide (SiO₂), silicon nitride (SIN), silicon oxynitride (SiON), silicon carbonitride (SiCN) or a high-k material (such as, hafnium silicon, hafnium oxide, hafnium silicon oxide or hafnium silicon oxynitride) and the arbitrary combinations thereof.

Next, the first gate electrode 122 is formed on the first gate dielectric layer 121; and the second gate electrode 132 is formed on the second gate dielectric layer 131, wherein the second gate electrode 132 and the first gate electrode 122 are separated from each other (as shown in FIG. 1C). In some embodiments of the present disclosure, the formation of the first gate electrode 122 and the second gate electrode 132 includes steps as follows: Firstly, a polysilicon layer (not shown) is formed on the device region A1 of the semiconductor substrate 101. Next, the polysilicon layer is patterned, remaining the portion of the polysilicon layer above the first gate dielectric layer 121 and the portion of the polysilicon layer above the second gate dielectric layer 131 to serve as the first gate electrode 122 and the second gate electrode 132 respectively. Wherein, the vertically stacked first gate dielectric layer 121 and the first gate electrode 122 constitute the first split gate structure 120; and the vertically stacked second gate dielectric layer 131 and the second gate electrode 132 constitute the second split gate structure 130.

Then, a plurality of spacers 112 are formed on the sidewalls of the first gate electrode 122 and the second gate electrode 132. At least one ion implantation process, using the combination of the first split gate structure 120, the second split gate structure 130 and the spacer 112 as a mask, is then performed to form a drain region 105 having the second electrical property (N-type electrical property) in the lightly doped region 104, and to form a lightly doped region 106 and a source region 107 both having the second electrical property (N-type electrical property) in the second well region 103. A silicide block (SAB) manufacturing process is next performed to form metal silicide layers 108 and 109 on the drain region 105 and the source region 106 to serve as the contact terminals of the drain region 105 and the source region 106 respectively.

In the present embodiment, as shown in FIG. 1C, the contact terminal (the metal silicide layer 108) of the drain region 105 is adjacent to the first gate dielectric layer 121 (or the portion of the spacer 112 adjacent to the first gate dielectric layer 121 covering the first split gate structure 120). The contact terminal (the metal silicide layer 109) of the source region 106 is adjacent to the second gate dielectric layer 131 (or another portion of the spacer 112 covering the second split gate structure 130). The doping concentration of the lightly doped regions 104 and 106 having the second electrical property (N-type electrical property) is substantially greater than the doping concentration of the native region 101A of the semiconductor substrate 101. The material constituting the metal silicide layers 108 and 109 is, for example, cobalt silicide (CoSi₂) or nickel silicide (NiSi).

Subsequently, a series of back-end-of-line (BEOL) process, including a metal damascene process, are performed through the to form an interlayer dielectric (ILDs) 119 covering the device region A1, and to form a metal interconnect structure (including via plugs 115, 116, 117 and 118) in the interlayer dielectric layer 119 to electrically connect the drain region 105, the source region 106, the first gate electrode 122 and the second gate electrode 132 to different connecting wires (such as, word lines 124A, bit lines 124B and gate conductors 124C) of a metal wiring layer 124, respectively. Whereby, the semiconductor device 100 as shown in FIG. 1D can be formed.

In the present embodiment, the first split gate structure 120 and the second split gate structure 130 may be electrically connected in parallel with each other through the via plugs 117 and 118 and the gate connecting wire 124C, so that the first split gate structure 120 and the second split gate structures 130 have the same gate voltage, and by modulating the thicknesses of the first gate dielectric layer 121 and the second gate dielectric layer 131, the output voltage of the drain region 105 can be controlled as greater than the input voltage of the source region 106.

In addition, the output voltage of the drain region 105 can be further increased by further expending the native region 101A of the semiconductor substrate 101 that separates the first well region 102 and the second well region 103 to enlarge the distance between the drain region 105 and the source region 106, and it can be ensured that the first gate dielectric layer 121 and the second gate dielectric layer 131 respectively formed on the first well region 102 and the second well region 103 can be separated from each other. Therefore, mutual interference occurs between different manufacturing processes for preparing the first gate dielectric layer 121 and the second gate dielectric layer 131 can be reduced; and it can prevent sharp protrusions or slopes from generating between the first gate dielectric layer 121 and the second gate dielectric layer 131 with different thicknesses. Such that, he problems of gate height loss in the nEDMOS transistor can be solved.

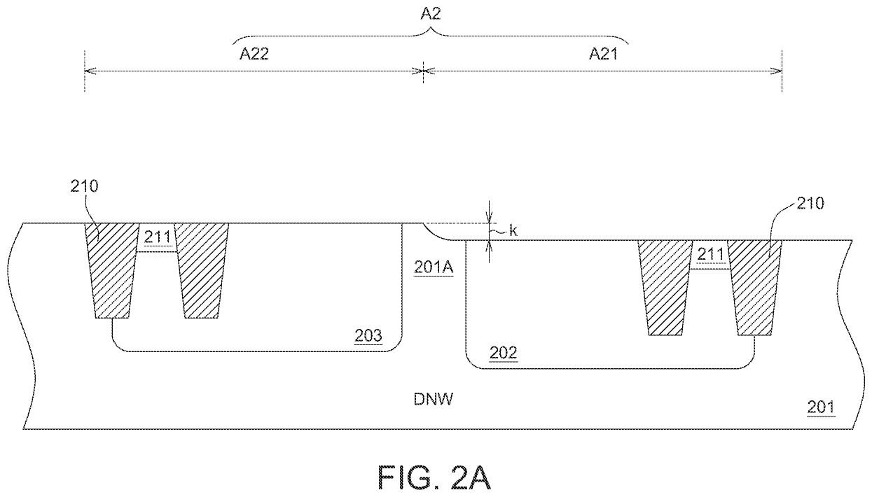

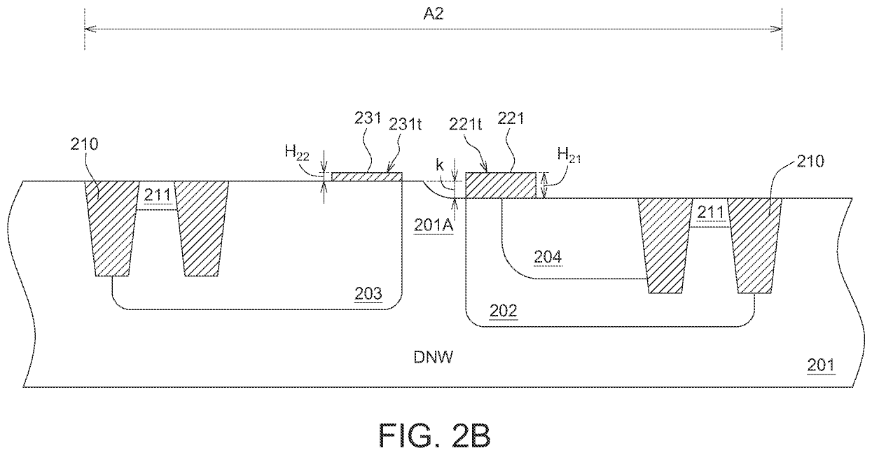

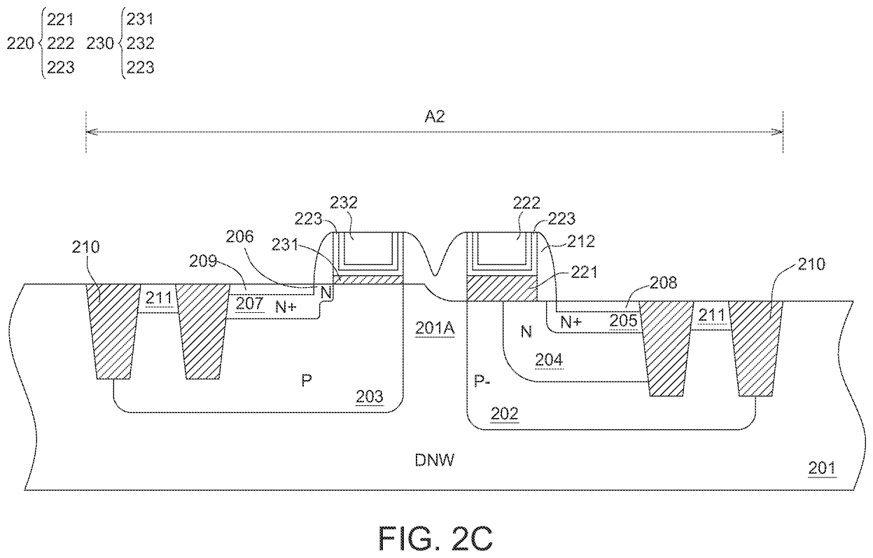

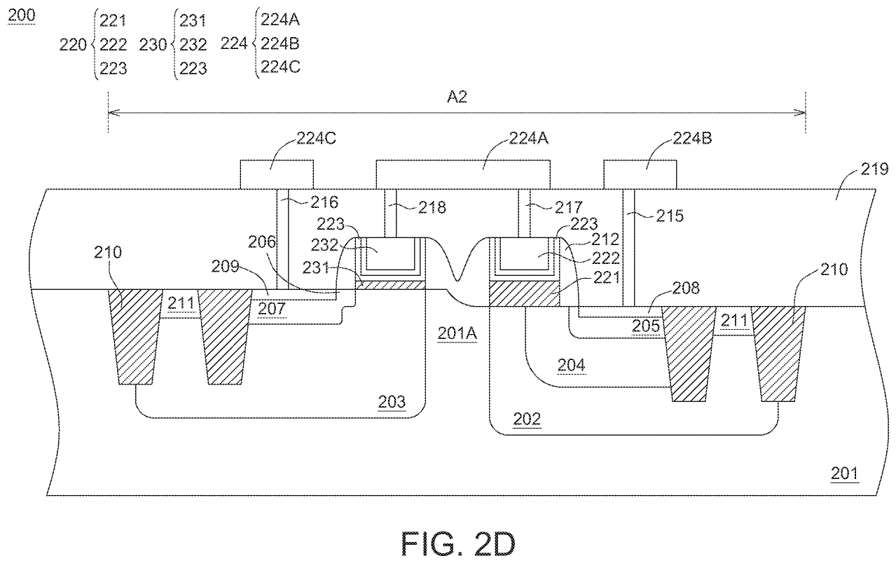

FIGS. 2A to FIG. 2D are cross-sectional views illustrating a series of processing structures for manufacturing a semiconductor device 200, according to another embodiment of the present disclosure. In some embodiments of the present disclosure, the semiconductor device 200 may be an nEDMOS transistor including a split metal gate structure. The method of manufacturing the semiconductor device 200 includes steps as follows:

Firstly, a semiconductor substrate 201 is provided, and a shallow trench isolation structure 210 is formed in the semiconductor substrate 201 to define an device region A2 in the semiconductor substrate 101 (as shown in FIG. 2A). In some embodiments of the present disclosure, the semiconductor substrate 201 may be a silicon substrate having an n-doped deep well region (DNW)).

Next, at least one ion implantation process is performed to form a first well region 202 and a second well region 203 that have the same electrical property and are separated from each other in the semiconductor substrate 201. And a lightly doped region 204 having the second electrical property (N-type electrical property) is then formed in the first well region 202. For example, in the present embodiment, the first well region 202 and the second well region 203 having the first electrical property (P-type electrical property) are simultaneously formed in the DNW (third well region) in the device region 2 of the semiconductor substrate 201 by the same ion doping process. The lightly doped region 204 having the second electrical property (N-type electrical property) is then formed in the second well region 202 of the semiconductor substrate 201 by another ion doping process. Wherein the first well region 202 and the second well region 203 are separated from each other by a portion of a native region 201A of the semiconductor substrate 201. And the doping concentration of the first well region 202 is smaller than the doping concentration of the second well region 203. In addition, two heavily doped regions 211 having the first electrical property (P-type electrical property) may be formed respectively in the first well region 202 and the second well region 203 by another ion doping process. The doping concentration of the heavily doped region 211 is greater than the doping concentration of the first well region 202.

Then, a photolithography etching process is performed to remove a portion of the semiconductor substrate 201 disposed in the device region A2, so as to form a height difference K between the etched portion A21 and the non-etched portion A22 of the device region A2. In this embodiment, the first well region 202 is included in the etched portion A21 of the device region A21; the first well region 202 is included in the non-etched portion A22 of the device region A22.

Thereafter, a first gate dielectric layer 221 with a first thickness H21 is formed on the first well region 202; and a second gate dielectric layer 231 with a second thickness H22 is formed on the second well region 203, wherein the first gate dielectric layer 221 and the second gate dielectric layer 231 are separated from each other, and the first thickness H21 is greater than the second thickness H22. In the present embodiment, as shown in FIG. 2B, the top surface 221t of the first gate dielectric layer 221 flush with the top surface 231t of the second gate dielectric layer 231.

Next, a replacement metal gate (RMG) manufacturing process is performed to form a first metal gate electrode 222 on the first gate dielectric layer 221; to form a second metal gate electrode 232 on the second gate dielectric layer 231, and to cause the second metal gate electrode 232 and the first metal gate electrode 222 separated from each other (as shown in 1C). In some embodiments of the present disclosure, the formation of the first metal gate electrode 222 and the second metal gate electrode 232 includes steps as follows: Firstly, a polysilicon layer (not shown) is formed on the device area A2 of the semiconductor substrate 201. The polysilicon layer is then patterned to remain the portion of the polysilicon layer on the first gate dielectric layer 221 and the portion of the polysilicon layer on the second gate dielectric layer 231 to serve as dummy gate electrodes (not shown).

Then, a plurality of spacers 212 are formed on the sidewalls of the dummy gate electrodes, and the dummy gate electrodes are removed to expose the first gate dielectric layer 221 and the second gate dielectric layer 231. A work function layer 223 with a multi-layer structure (barrier layer) is formed respectively on the first gate dielectric layer 221 and the second gate dielectric layer 231, and then a first metal gate electrode 222 and a second metal gate electrode 222 are formed on the work function layer 223 and respectively fills the remained positions of the removed dummy gate electrodes. Thereby, the vertically stacked first gate dielectric layer 221, a portion of the work function layer 223 and the first gate electrode 222 constitute the first split gate structure 220; the vertically stacked second gate dielectric layer 231, another portion of the work function layer 223 and second gate electrode 232 form a second split gate structure 230.

At least one ion implantation process, using the combination of the first split gate structure 220, the second split gate structure 230 and the spacer 212 as a mask, is then performed to form a drain region 205 having the second electrical property (N-type electrical property) in the lightly doped region 204, and to form a lightly doped region 206 and a source region 207 both having the second electrical property (N-type electrical property) in the second well region 203. A silicide block (SAB) manufacturing process is next performed to form metal silicide layers 208 and 209 on the drain region 205 and the source region 206. As shown in FIG. 2C, the drain region 205 is adjacent to the first gate dielectric layer 221 (or the portion of the spacer 212 adjacent to the first gate dielectric layer 221 covering the first split gate structure 220). The source region 206 is adjacent to the second gate dielectric layer 231 (or another portion of the spacer 212 covering the second split gate structure 230). In the present embodiment, the doping concentration of the lightly doped regions 204 and 206 having the second electrical property (N-type electrical property) is substantially greater than the doping concentration of the native region 201A of the semiconductor substrate 201.

Subsequently, a series of back-end-of-line (BEOL) process, including a metal damascene process, are performed through the to form an interlayer dielectric (ILDs) 219 covering the device region A2, and to form a metal interconnect structure (including via plugs 215, 216, 217 and 218) in the interlayer dielectric layer 219 to electrically connect the drain region 205, the source region 206, the first gate electrode 222 and the second gate electrode 232 to different connecting wires (such as, word lines 224A, bit lines 224B and gate conductors 224C) of a metal wiring layer 224, respectively. Whereby, the semiconductor device 200 as shown in FIG. 2D can be formed.

In the present embodiment, the first split gate structure 220 and the second split gate structure 230 may be electrically connected in parallel with each other through the via plugs 217 and 218 and the gate connecting wire 224C, so that the first split gate structure 220 and the second split gate structures 230 have the same gate voltage, and by modulating the thicknesses of the first gate dielectric layer 221 and the second gate dielectric layer 231, the output voltage of the drain region 205 can be controlled as greater than the input voltage of the source region 206.

Since the first well region 202 and the second well region 203 are separated from each other by the native region 201A of the semiconductor substrate 201, thus the first gate dielectric layer 221 and the second dielectric layer 231 that are respectively formed on the first well region 202 and the second well region 203 can be separated from each other. Therefore, the drain current drop of the drain region 205 (like the conventional device) due to the overlapping of the first well region 202 adjacent to the drain region 205 and the second gate dielectric layer 231 adjacent to the source region 206 can be prevented. In addition, mutual interference occurs between different manufacturing processes for preparing the first gate dielectric layer 221 and the second gate dielectric layer 231 can be reduced; and it can prevent sharp protrusions or slopes from generating between the first gate dielectric layer 221 and the second gate dielectric layer 231 with different thicknesses. Such that, he problems of gate height loss in the nEDMOS transistor can be solved.

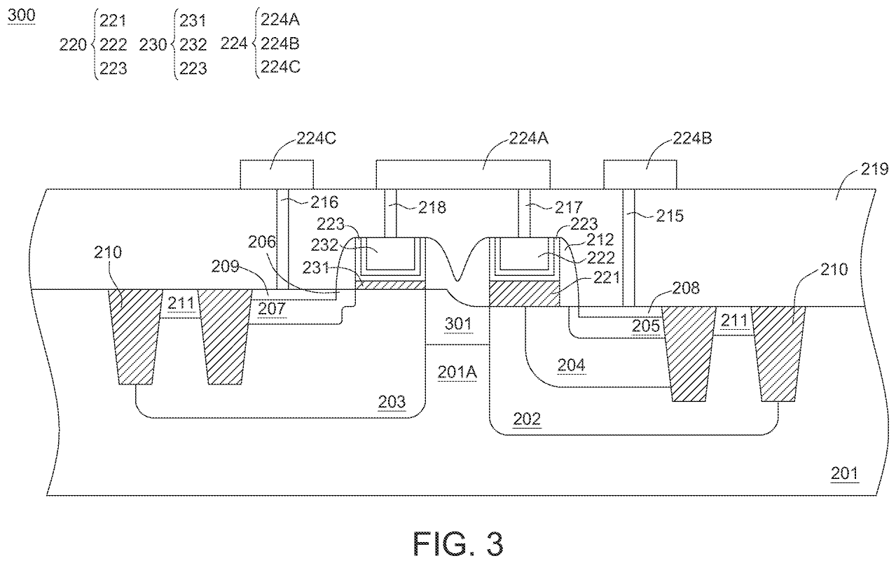

FIG. 3 is a cross-sectional view of a semiconductor device 300 according to yet another embodiment of the present disclosure. The structure of the semiconductor device 300 is generally similar to that of the semiconductor device 200 as shown in FIG. 2D. The difference there between is that the semiconductor device 300 further includes a lightly doped region 301 disposed in the native region 201A of the semiconductor substrate 201. The lightly doped region 301 has the second electrical property (N-type electrical property) and has a doping concentration greater than that of the native region 201A (or the n-doped deep well region DNW). In the present embodiment, the doping concentration of the lightly doped region 301 is substantially equal to the doping concentration of the lightly doped regions 204 and 206. The on-resistance between the drain electrode 205 and the source electrode 206 of the semiconductor element 300 can be further reduced (or the drain current can be increased) by applying the lightly doped region 301.

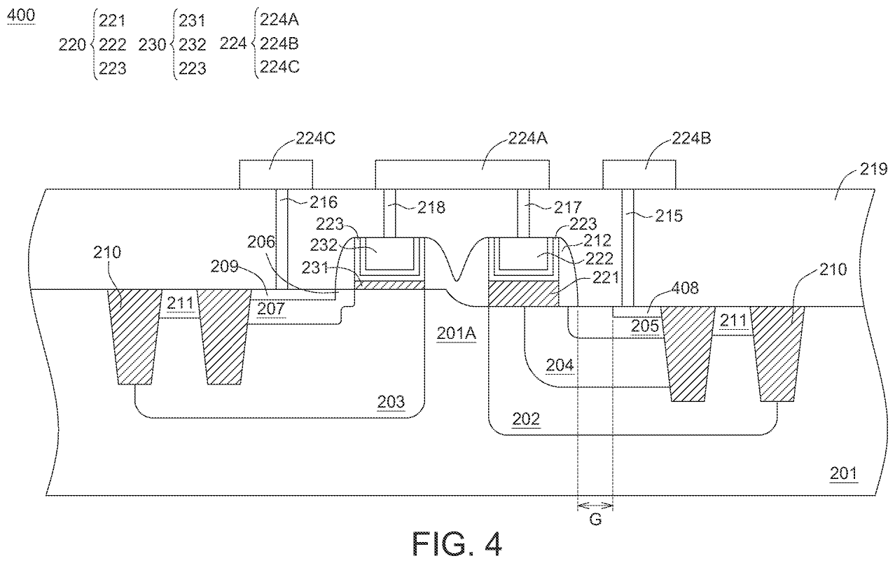

FIG. 4 is a cross-sectional view of another semiconductor device according to yet another embodiment of the present disclosure. The structure of the semiconductor device 400 is generally similar to that of the semiconductor device 200 as shown in FIG. 2D. The difference there between is that there is a distance G between the contact terminal (the metal silicide layer 408) of the drain region 205 and the first split gate structure 220 in the semiconductor device 400, which can effectively reduce gate-induced-drain-leakage (GIDL) due to the high electric field of the gate.

In accordance with the aforementioned embodiments of the present disclosure, a semiconductor device with a split gate structure is provided. Wherein, the split gate structure of the semiconductor device includes a first split gate structure and a second split gate structure that are separated from each other, and are independently formed on a first well region and a second well region that are separated from each other and that have the same electrical property. Since the first well region and the second well region are separated by a portion of the substrate body region, thus it can prevent the portion of the second well region close to the drain terminal from overlapping with the portion of the second split gate structure close to the source terminal, whereby the problems of drain current drop due to the overlapping can be resolved.

In addition, since the first gate dielectric layer and the second gate dielectric layer of the first split gate structure and the second split gate structure are respectively formed on the first well region and the second well region that are separated from each other, thus the manufacturing processes for forming these two may not interfere with each other, and no tip protrusions or slopes are generated at the adjacencies between the two, whereby it can ensure each of the first gate electrode and the second gate electrode that are subsequently formed on the first gate dielectric layer and the second gate dielectric layer has a preset height after planarization correspondingly without causing gate height loss.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a substrate;
a first well region, disposed in the substrate and having a first electrical property;
a second well region, disposed in the substrate, separated from the first well region, and having the first electrical property;
a first gate dielectric layer, disposed on the first well region and has a first thickness;
a second gate dielectric layer, disposed on the second well region, separated from the first gate dielectric layer, and having a second thickness less than the first thickness;
a first gate electrode, disposed on the first gate dielectric layer;
a second gate electrode, disposed on the second gate dielectric layer and separated from the first gate electrode;
a drain region, disposed in the first well region; and
a source region, disposed in the second well region.

2. The semiconductor device according to claim 1, wherein the first well region has a doping concentration smaller than that of the second well region.

3. The semiconductor device according to claim 1, wherein the first well region and the second well region are separated from each other by a native region of the substrate.

4. The semiconductor device according to claim 3, wherein the first well region and the second well region both are disposed in a third well region of the substrate, and the native region is disposed in the third well region.

5. The semiconductor device according to claim 3, wherein the third well region and the native region have a second electrical property, and the first well region has a doping concentration greater than that of the native region.

6. The semiconductor device according to claim 3, further comprising a lightly doped region disposed in the native region, wherein the lightly doped region has the second electrical property and has a doping concentration greater than that of the native region.

7. The semiconductor device according to claim 1, wherein the first gate dielectric layer has a top surface substantially flush with a top surface of the second gate dielectric layer, and the first gate electrode and the second gate electrode include metal.

8. The semiconductor device according to claim 1, wherein the first gate dielectric layer has a bottom surface substantially flush with a bottom surface of the second gate dielectric layer, and the first gate electrode and the second gate electrode include polysilicon.

9. The semiconductor device according to claim 1, wherein a contact terminal of the source region is adjacent to the second gate dielectric layer, and there is a distance between a contact terminal of the drain region and the first gate dielectric layer.

10. The semiconductor device according to claim 1, further comprising a metal wiring disposed on the first gate electrode and the second gate electrode to electrically connect the two.

11. A method for fabricating a semiconductor device, comprising:
forming a first well region and a second well region both with a first electrical property in a substrate, wherein the first well region and the second well region are separated from each other;
forming a first gate dielectric layer with a first thickness on the first well region;
forming a second gate dielectric layer with a second thickness on the second well region, wherein the first gate dielectric layer and the second gate dielectric layers are separated from each other, and the first thickness is greater than the second thickness;
forming a first gate electrode on the first gate dielectric layer;
forming a second gate electrode on second gate dielectric layer, wherein the second gate electrode and the first gate electrode are separated from each other;
forming a drain region in the first well region; and
forming a source region in the second well region.

12. The method according to claim 11, prior to forming the first well region and the second well region, further comprising:
forming a third well region having a second electrical property in the substrate; and
forming the first well region and the second well region in the third well region, to make the first well region and the second well region separated from each other by a native region having the second electrical property.

13. The method according to claim 12, further comprising forming a lightly doped region having the second electrical property in the native region, wherein the lightly doped region has a doping concentration greater than that of the native region.

14. The method according to claim 11, prior to forming the first gate dielectric layer, further comprising forming a lightly doped region with the second electrical property in the first well region.

15. The method according to claim 11, prior to forming the first gate dielectric layer, further comprising removing a portion of the semiconductor substrate disposed, so as to form a height difference between an etched portion and an non-etched portion of the semiconductor substrate.

16. The method according to claim 15, wherein forming the first gate electrode comprises performing a replacement metal gate (RMG) manufacturing process.

17. The method according to claim 11, further comprising forming a metal wiring on the first gate electrode and the second gate electrode to electrically connect the two.

18. The method according to claim 11, further comprising forming a metal silicide layer on the drain region, to make that there is a distance between the metal silicide layer and the first gate dielectric layer.
